(19) United States
(12) Patent Application Publication
(10) Pub. No.: US 2021/0222857 A1
(43) Pub. Date: Jul. 22, 2021

(54) EXTERNAL ELECTRONIC DEVICE

(71) Applicant: ASUSTEK COMPUTER INC., TAIPEI (TW)

(72) Inventors: Li-Chen CHAN, TAIPEI (TW); Tong-Shen HSIUNG, TAIPEI (TW); Ming-Chih HUANG, TAIPEI (TW); Meng-Chu HUANG, TAIPEI (TW); Shang-Chih LIANG, TAIPEI (TW); Fu-Yu CAI, TAIPEI (TW); Chia-Hao HUNG, TAIPEI (TW)

(21) Appl. No.: 17/152,547

(22) Filed: Jan. 19, 2021

(30) Foreign Application Priority Data
Jan. 20, 2020 (CN) 202010064455.5

(51) Int. Cl. F21V 15/01; H05K 5/02

(52) U.S. Cl. CPC F21V 15/01; H05K 5/02

(57) ABSTRACT

A light-transmitting plastic casing and a manufacturing method thereof are provided. A manufacturing method of a light-transmitting plastic casing include the steps: providing a mixed material, the mixed material includes a resinous material, a flame retardant material, a transparent fiberglass material, and an elastomer material; performing a granulating step to the mixed material to form granules; performing a heating step to the granules; and performing a molding step to heated granules to form a light-transmitting plastic casing.

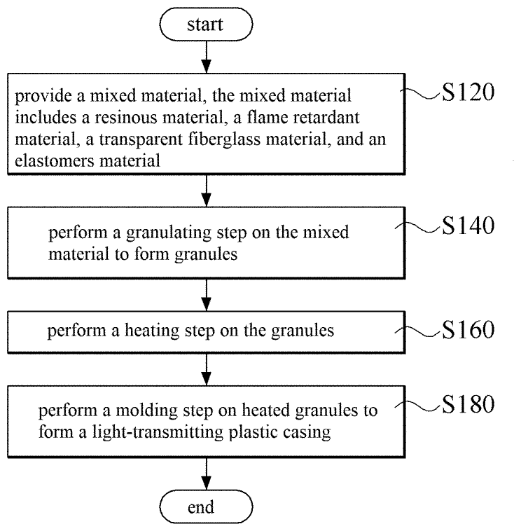

### CROSS-REFERENCE TO RELATED APPLICATION

This application claims the priority benefit of Chinese application serial No. 202010064455.5, filed on Jan. 20, 2020. The entirety of the above-mentioned patent application is hereby incorporated by reference herein and made a part of specification.

### BACKGROUND OF THE INVENTION

### Field of the Invention

The disclosure relates to a plastic casing and a manufacturing method and, more particularly, relates to a light-transmitting plastic casing of an electronic device and a manufacturing method.

### Description of the Related Art

With an advancement of technology, an electronic product market becomes more and more competitive. Visual and tactile effects of casings become important. Plastic casings are widely used in various electronic devices due to advantages of light weight, low cost, and simple processing.

However, conventional plastic casings cannot maintain sufficient material strength while providing a translucent appearance texture to attract attention of consumers to see through a design of internal components of electronic products.

### BRIEF SUMMARY OF THE INVENTION

A manufacturing method of a light-transmitting plastic casing is provided. The manufacturing method comprises: providing a mixed material, the mixed material includes a resinous material, a flame retardant material, a transparent fiberglass material, and an elastomer material; performing a granulating step to the mixed material to form granules; performing a heating step to the granules; and performing a molding step to the heated granules to form a light-transmitting plastic casing.

Based on the manufacturing method of a light-transmitting plastic casing of the disclosure, sufficient bending modulus and impact resistance of a casing are improved, and the light transmittance feature is also good for transparency.

### BRIEF DESCRIPTION OF THE DRAWINGS

The FIGURE is a schematic diagram showing a manufacturing method of a light-transmitting plastic casing in an embodiment.

### DETAILED DESCRIPTION OF THE EMBODIMENTS

Embodiments are described in more detail with reference to drawings. The advantages and features of the disclosure will be clearer based on the following description and the scope of the disclosure. The drawings are simplified and have inaccurate proportions, which are only used to conveniently and clearly explain the embodiments.

The FIGURE is a schematic diagram showing a manufacturing method of a light-transmitting plastic casing in an embodiment. The manufacturing method of the light-transmitting plastic casing in the embodiment includes the following steps.

In step S120, a mixed material is provided. The mixed material includes a resinous material, a flame retardant material, a transparent fiberglass material, and an elastomer material.

In an embodiment, a proportion of the transparent fiberglass material in the mixed material is from 7% to 15% to provide light transmittance and material elasticity. In an embodiment, the flame retardant material includes a silicon based flame retardant and a phosphate ester material to provide a good anti-dripping effect. In the embodiment, the anti-dripping agent is not added to avoid the negative effect on the light transmittance. In an embodiment, the resinous material is a high melt flow rate resinous material to facilitate the granulating step.

The elastomer material in the mixed material improves toughness of the material. In an embodiment, the elastomer material is a thermoplastic elastomer material. In an embodiment, in step S120, the refractive index of the elastomer material is equal to the refractive index of the resinous material to reduce the negative effect of the elastomer material on the light transmittance.

In an embodiment, the proportion of the elastomer material in the mixed material is less than the proportion of the transparent fiberglass material to reduce the effect of the elastomer material on the light transmittance. In an embodiment, the resinous material is a polycarbonate (PC) resinous material, and the elastomer material is a polyamide elastomer material.

In an embodiment, the epoxy resin material and the coupling agent are added to the mixed material to improve directivity of the transparent fiberglass material, consistency between the transparent fiberglass material and the resinous material, and rigidity of the light-transmitting plastic casing.

In step S140, the granulating step is performed to the mixed material to form the granules for subsequent steps. In an embodiment, the granulating step is performed via a screw extruder. In an embodiment, to mix the mixed material evenly, the screw extruder is a double-screw extruder or a multiple-screw extruder, which is not limited herein. In an embodiment, other equipment which are adapted for mixing and granulating polymer materials may be used, such as a rotor type mixer.

In an embodiment, in the granulating step, an antioxidant gas, such as Nitrogen, is added to avoid yellowing due to the oxidation of the mixed material during extrusion.

In step S160, a heating step is performed to the granules. In order to ensure that the granules are dried effectively and avoid qualitative changes of polymer materials at a high temperature, in an embodiment, in the heating step, the granules are heated at a temperature that ranges from 115° C. to 125° C. for more than 4 hours.

In step S180, the molding step is performed to the heated granules to form a light-transmitting plastic casing. In an embodiment, the molding step is an injection molding step, which is not limited herein. In an embodiment, the molding step includes a sheet forming step and a mold forming step. In the sheet forming step, sheets are formed via granules. For example, the sheets are formed by rolling or extrusion. A mold is used to shape the sheet in the mold forming step.

In an embodiment, manufacturing parameters and the cost of the mixed materials for the transparent plastic shell manufacturing method are described below.

In an embodiment, the constituent and proportions of the mixed material used in the granule step are shown in the following table (Table 1).

| Raw Material | Proportion |
|---|---|
| Polycarbonate (PC), molecular weight | 67.1% |
| Mn = 19000 | |
| Fiberglass (fiberglass product model | 10% |
| 415A, Owens Corning) | |
| Liquid silicone flame retardant (flame | 3% |
| retardant product model KR480, | |
| Shin-Etsu Chemical Industry) | |
| Phosphate ester flame retardant (flame | 15% |
| retardant product model CR741, Daba | |
| Chemical) | |
| Polyamide elastomer | 3% |
| Epoxy resin (epoxy resin product model | 0.3% |
| JER1010, Mitsubishi Chemical) | |
| Coupling agent (coupling agent product | 0.8% |
| model KBE303, Shin-Etsu Chemical | |
| Industry) | |
| Antioxidant (Antioxidant P-EPQ, | 0.3% |
| Germany Clariant) | |
| PE-based lubricant | 0.5% |

The parameters of the granulating step are as follows. The granulating step is performed via a double-screw extruder at 270-310° C., and the rotation speed is 350 rpm. The parameters are varied depending on the granulating device, the composition and the mixing state of the mixed material, and the required production speed.

For example, to increase the mixing state of materials and the production speed of granules, the rotation speed is increased (for example, to 400 to 450 rpm). The extrusion temperature is adjusted according to the type of resin material in the mixed material and the proportion of the transparent glass fiber material to make sure that the materials are fully mixed and the substrate (resin material) in the mixed material would not be degraded at the high temperature. In an embodiment, the extrusion temperature is at least 30° C. higher than the melting point of the resin material to ensure that the materials are fully mixed.

In an embodiment, in the heating step, the granules are heated at a temperature that ranges from 115° C. to 125° C. for more than 4 hours. The molding step is performed via an injection molding.

The flexural modulus of the light-transmitting plastic casing in the embodiment is more than 4200 MPa. As a result, the light-transmitting plastic casing includes a good capability to resist falling ball impact and good light transmittance.

Via a manufacturing method of a light-transmitting plastic casing in embodiments, sufficient bending modulus and impact resistance of the casing are maintained, and light transmittance is good to provide a transparent appearance texture.

Although the present invention has been described in considerable detail with reference to certain preferred embodiments thereof, the disclosure is not for limiting the scope of the invention. Persons having ordinary skill in the art may make various modifications and changes without departing from the scope. Therefore, the scope of the appended claims should not be limited to the description of the preferred embodiments described above.

What is claimed is:

1. A manufacturing method of a light-transmitting plastic casing, comprising:
providing a mixed material, the mixed material includes a resinous material, a flame retardant material, a transparent fiberglass material, and an elastomer material;
performing a granulating step to the mixed material to form granules;
performing a heating step to the granules; and
performing a molding step to the heated granules to form the light-transmitting plastic casing.

2. The manufacturing method of the light-transmitting plastic casing according to claim 1, wherein a proportion of the transparent fiberglass material in the mixed material is from 7% to 15%.

3. The manufacturing method of the light-transmitting plastic casing according to claim 1, wherein the flame retardant material includes a silicon based flame retardant and a phosphate ester material.

4. The manufacturing method of the light-transmitting plastic casing according to claim 1, wherein the resinous material is a polycarbonate (PC) resinous material.

5. The manufacturing method of the light-transmitting plastic casing according to claim 1, wherein the elastomer material is a polyamide elastomer material.

6. The manufacturing method of the light-transmitting plastic casing according to claim 1, wherein a refractive index of the elastomer material is equal to the refractive index of the resinous material, a proportion of the elastomer material in the mixed material is less than a proportion of the transparent fiberglass material in the mixed material.

7. The manufacturing method of the light-transmitting plastic casing according to claim 1, wherein the mixed material includes an epoxy resin material and a coupling agent to improve rigidity of the light-transmitting plastic casing.

8. The manufacturing method of the light-transmitting plastic casing according to claim 1, wherein nitrogen is added in the granulating step to avoid oxidization of the mixed material, and an extrusion temperature at the granulating step is more than 30° C. higher than a melting point of the resinous material.

9. The manufacturing method of the light-transmitting plastic casing according to claim 1, wherein the granulating step is performed via a double-screw extruder.

10. The manufacturing method of the light-transmitting plastic casing according to claim 1, wherein the granules are heated at a temperature that ranges from 115° C. to 125° C. for four hours in the heating step.

11. The manufacturing method of the light-transmitting plastic casing according to claim 1, wherein the molding step is an injection molding step.

12. The light-transmitting plastic casing, made by the manufacturing method of the light-transmitting plastic casing according to claim 1.
